(19) United States
(12) Patent Application Publication
(10) Pub. No.: US 2026/0033325 A1
(43) Pub. Date: Jan. 29, 2026

(54) APPARATUS INCLUDING MIM CAPACITOR

(71) Applicant: MICRON TECHNOLOGY, INC., Boise, ID (US)

(72) Inventors: HARUNOBU KONDO, Sagamihara (JP); Wataru Nobehara, Osaka-shi (JP)

(73) Assignee: MICRON TECHNOLOGY, INC., Boise, ID (US)

(21) Appl. No.: 19/271,315

(22) Filed: Jul. 16, 2025

Related U.S. Application Data
(60) Provisional application No. 63/675,117, filed on Jul. 24, 2024.

(51) Int. Cl. H01L 23/522; H01L 23/528; H10B 12/00

(52) U.S. Cl. CPC H01L 23/5223; H01L 23/5286; H10B 12/00

(57) ABSTRACT

Some embodiments of the disclosure provide an apparatus comprising: a plurality of upper wirings each extending in a first horizontal direction, a plurality of lower wirings each extending in a second horizontal direction perpendicular to the first horizontal direction; and a plurality of metal-insulator-metal (MIM) capacitors each extending at an intermediate angle between the first horizontal direction and the second horizontal direction.

### CROSS-REFERENCE TO RELATED APPLICATIONS

This application claims the filing benefit of U.S. Provisional Application No. 63/675,117, filed Jul. 24, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). Semiconductor memory devices may include metal-insulator-metal (MIM) capacitors as, for example, compensation capacitors for stable power supply to various circuits, individual components, and the like.

### BRIEF DESCRIPTION OF THE DRAWINGS

FIGS. 1 and 2 each depict an example configuration of at least part of an apparatus including an MIM capacitor according to an embodiment of the disclosure.

FIGS. 3-6 each depict an example configuration of at least part of an apparatus including an MIM capacitor according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for case of illustration. In the drawings, the dimensions and dimensional ratios of each unit do not necessarily match the actual dimensions and dimensional ratios in the embodiments.

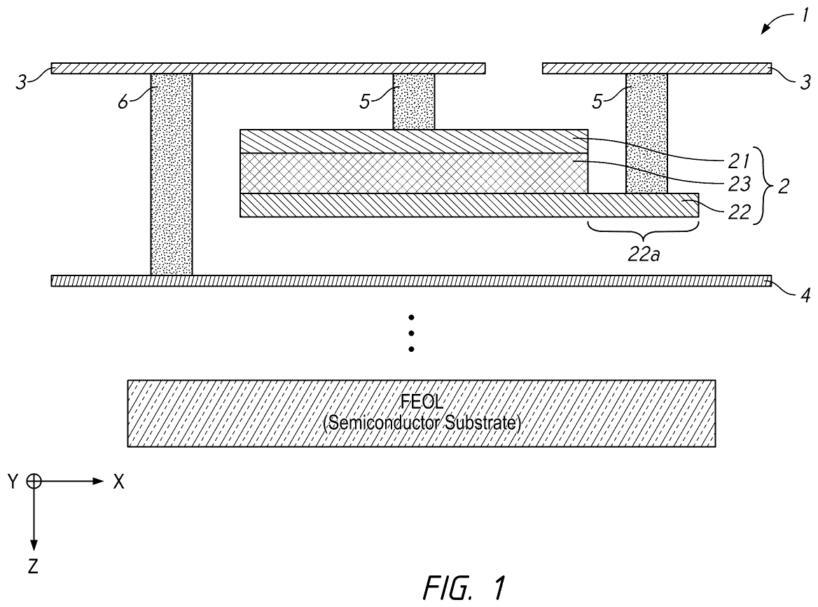

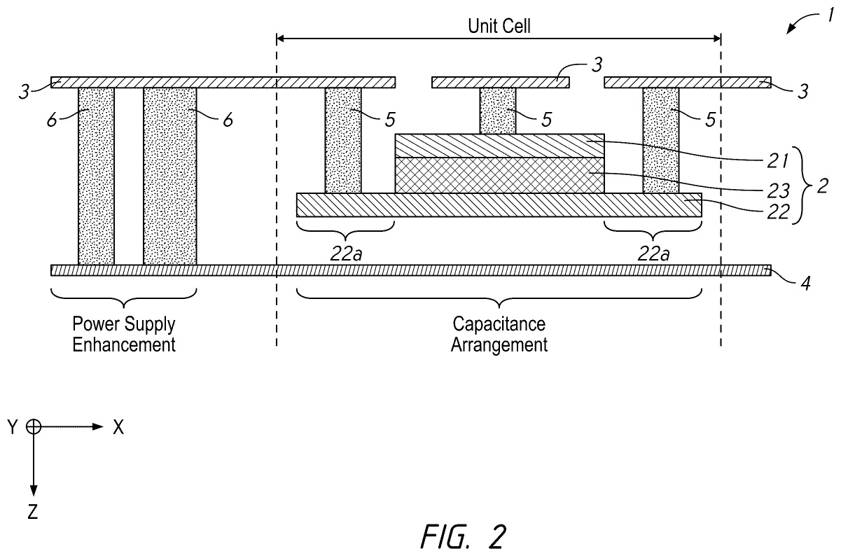

FIGS. 1 and 2 each depict an example configuration of at least part of an apparatus 1 including a metal-insulator-metal (MIM) capacitor 2 according to an embodiment of the disclosure. The apparatus 1 may be a semiconductor device. The semiconductor device may be a memory device. The memory device may be a dynamic random-access memory (DRAM). The apparatus 1 includes the MIM capacitor 2 between one or more upper wirings 3 and one or more lower wirings 4.

The upper wirings 3 may extend in a first horizontal direction (for example, an X-axis direction in the drawing). The lower wirings 4 may extend in a second horizontal direction (for example, a Y-axis direction in the drawing) perpendicular to or substantially perpendicular to the first horizontal direction. The upper wirings 3 and the lower wirings 4 may be provided in an upper metal layer and a lower metal layer, respectively. The upper wirings 3 and the lower wirings 4 may include conductive materials. The upper wirings 3 and the lower wirings 4 may supply power to various circuits, individual components, and the like that are coupled to the upper wirings 3 and/or the lower wirings 4.

The MIM capacitor 2 includes a top metal 21 and a bottom metal 22 with an insulator 23 therebetween. In one instance, the MIM capacitor 2 may be coupled to the upper wirings 3 by one or more vias 5 which extend in a vertical direction (for example, a Z-axis direction in the drawing). The vias 5 may include conductive materials. In another instance, the MIM capacitor 2 may be coupled to the lower wirings 4 by other vias (not separately depicted). In still another instance, the MIM capacitor 2 may be coupled to both the upper wirings 3 and the lower wirings 4. In the depicted example configuration, both the top metal 21 and the bottom metal 22 are coupled to the upper wirings 3 by the vias 5. The bottom metal 22 may include one or more protruding parts 22a for via coupling. Each protruding part 22a projects outward in the first horizontal (X-axis) direction so that the via 5 can be provided to vertically extend from or to the corresponding upper wiring 3 without being blocked by the top metal 21 and the insulator 23 above the bottom metal 22.

The upper and lower wirings 3 and 4 may be coupled to each other by one or more vias 6 to enhance the power supply. The vias 6 may include conductive materials. The MIM capacitor 2 between the upper and lower wirings 3 and 4 may be a compensation capacitor to stabilize the power supply. The MIM capacitor 2 may be arranged at a position to avoid the vias 6. In the depicted example configuration, the via 6 for power supply enhancement is provided on one side (the left side of the drawing) of the MIM capacitor 2 in the X-axis direction. Although not separately depicted, another via 6 may also be provided on another side (the right side of the drawing) of the MIM capacitor 2 in the X-axis direction, and another MIM capacitor 2 may further be provided next to the via 6. The via 6 and the MIM capacitor 2 may be repeatedly provided adjacent to each other with a certain pitch.

The MIM capacitor 2, the upper and lower wirings 3 and 4, and the vias 5 and 6 may be provided in a portion fabricated by a back-end-of-line (BEOL) process above a portion fabricated by a front-end-of-line (FEOL) process. The FEOL-fabricated portion may include individual components or devices, such as transistors, patterned in a semiconductor substrate. The BEOL-fabricated portion may include multiple metal layers stacked on the semiconductor substrate (or a wafer patterned with the devices). The metal layers may include wirings, interconnects, and the like for connecting the individual devices. The MIM capacitor 2 may be provided between certain metal layers. The MIM capacitor 2 may be provided between a top metal layer and a layer below the top metal layer among the multiple metal layers.

Since the MIM capacitor 2 may need to be arranged at a position to avoid the vias 6 as shown in FIGS. 1 and 2, there is a trade-off between capacitance arrangement and power enhancement. Designing of a power supply network with a certain pitch that can achieve efficient reduction of resistance and designing of a unit cell that fits within the pitch may thus be appropriately determined. The unit cell may include the MIM capacitor 2, at least a portion of the upper and lower wirings 3 and 4, and the vias 5. However, the more types of power supply or power source used, the more complex the combination of power supply enhancement and compensation capacitance becomes. As such combination becomes more complex, the top metal 21 of the MIM capacitor 2 may become smaller and the MIM capacitor 2 may become less efficient as a capacitive element.

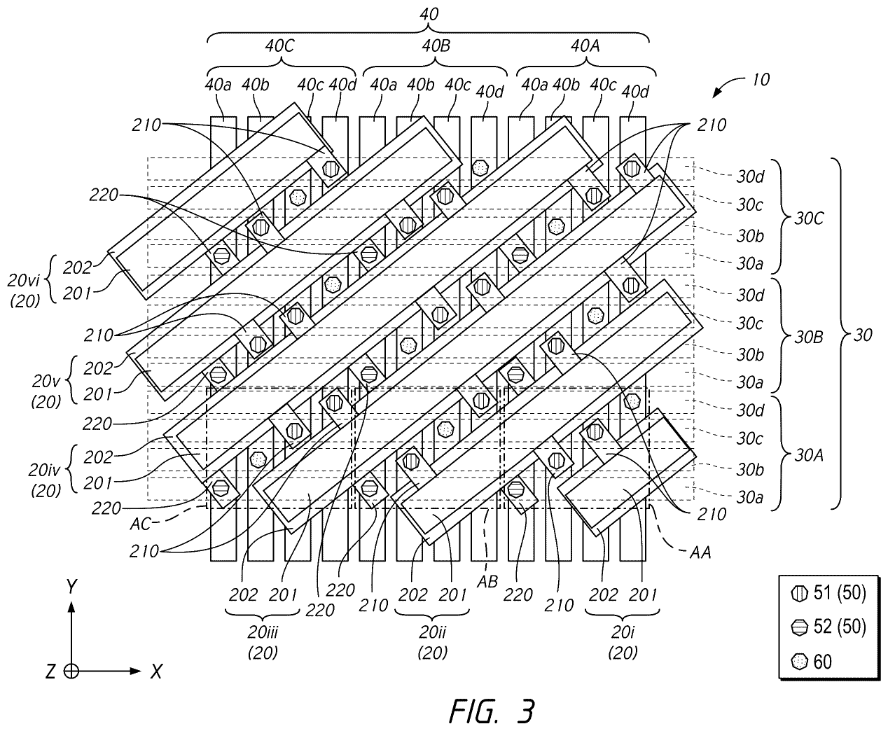

FIGS. 3-6 each depict an example configuration of at least part of an apparatus 10 including an MIM capacitor according to an embodiment of the disclosure. The apparatus 10 may be a semiconductor device. The semiconductor device may be a memory device. The memory device may be a DRAM. The apparatus 10 includes a plurality of upper wirings 30, a plurality of lower wirings 40, and a plurality of MIM capacitors 20. In a similar manner to the example configurations depicted in FIGS. 1 and 2, the MIM capacitors 20 (20i-20vi) are arranged between the upper wirings 30 and the lower wirings 40. For case of illustration, in FIGS. 3-6, the upper wirings 30 are illustrated with dotted lines so that the details of the underlying elements, such as the MIM capacitors 20, can be easily seen in plan view.

The upper wirings 30 each extend in a first horizontal direction (for example, an X-axis direction in the drawing) and are arranged in parallel with one another in a second horizontal direction (for example, a Y-axis direction) perpendicular or substantially perpendicular to the first horizontal direction. The upper wirings 30 each may have an elongate shape in the X-axis direction. The upper wirings 30 may be regularly spaced with a predetermined pitch in the Y-axis direction. The lower wirings 40 each extend in the second horizontal (Y-axis) direction and are arranged in parallel with one another in the first horizontal (X-axis) direction. The lower wirings 40 each may have an elongate shape in the Y-axis direction. The lower wirings 40 may be regularly spaced with a predetermined pitch in the X-axis direction. The upper wirings 30 and the lower wirings 40 may be arranged in an upper metal layer and a lower metal layer, respectively. The upper wirings 30 and the lower wirings 40 are orthogonal (or substantially orthogonal within reasonable tolerances of fabrication, measurement, etc.) to each other and form a mesh configuration in plan view. The mesh configuration may also be referred to as a wiring mesh. The upper wirings 30 and the lower wirings 40 may include conductive materials. The upper wirings 30 and the lower wirings 40 may be configured to supply power to various circuits, individual components, and the like coupled to the upper wirings 30 and/or the lower wirings 40. The upper and lower wirings 30 and 40 may be power supply wirings.

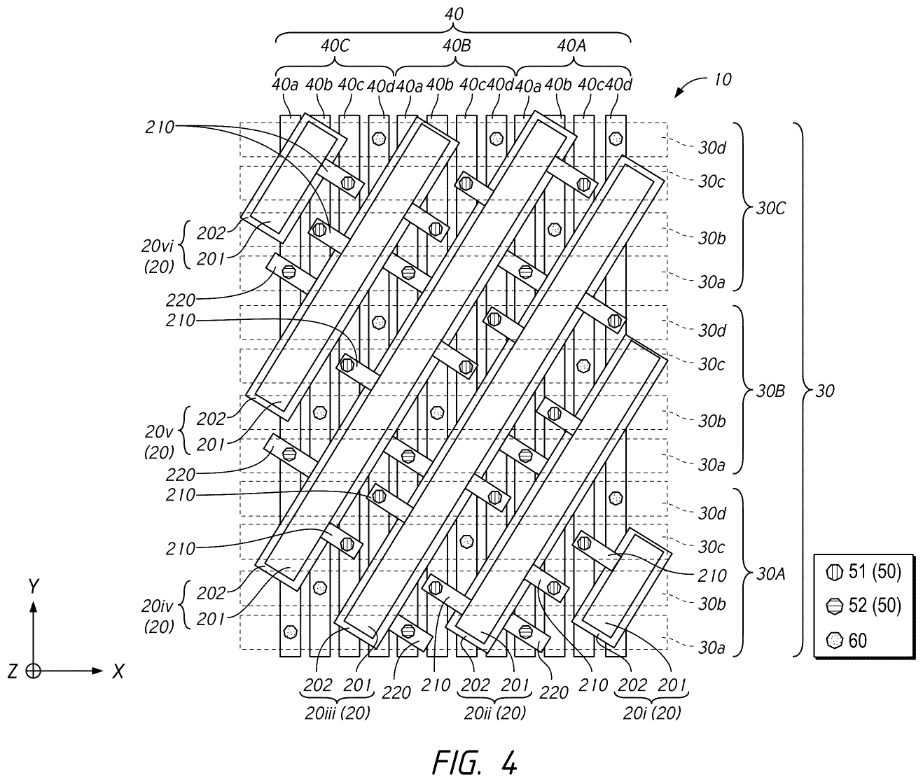

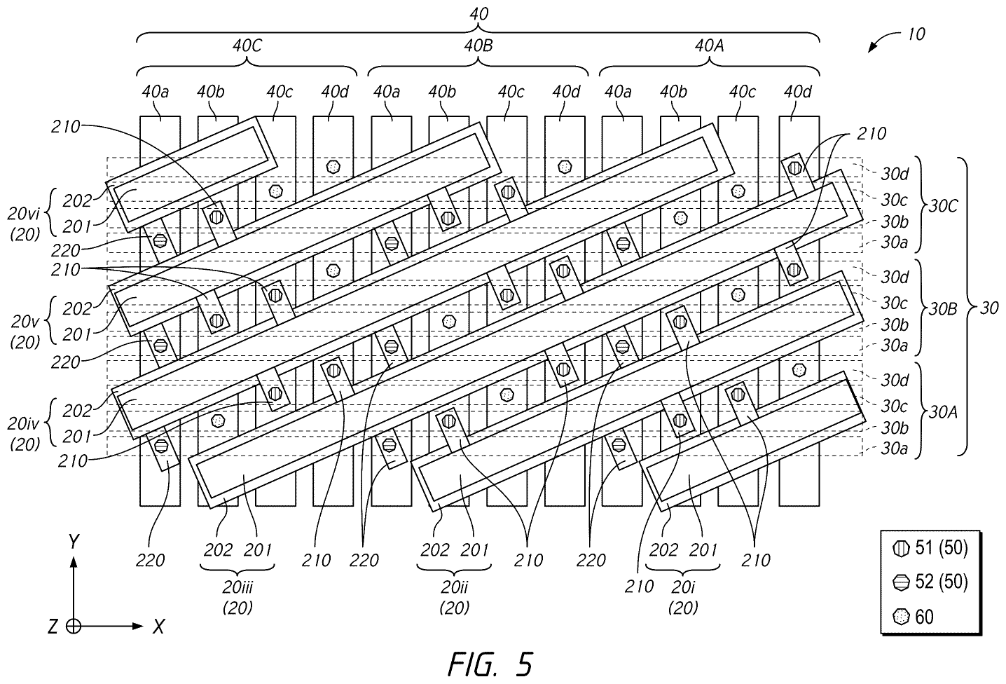

The MIM capacitors 20 are arranged between the upper wirings 30 and the lower wirings 40 and are coupled to at least one of the upper wirings 30 or the lower wirings 40. The MIM capacitors 20 each may be a compensation capacitor. The compensation capacitor may be for stabilizing the power supply. The MIM capacitors 20 each extend at an intermediate angle between the first horizontal direction of the upper wirings 30 and the second horizontal direction of the lower wirings 40. The first horizontal direction of the upper wirings 30 and the second horizontal direction of the lower wirings 40 may also be referred to as an upper wiring direction and a lower wiring direction, respectively. The direction in which each MIM capacitor 20 extends may also be referred to as a longitudinal direction or a lengthwise direction of the MIM capacitor 20. Each MIM capacitor 20 are elongate in the longitudinal direction. The MIM capacitors 20 are arranged in parallel with one another in an orthogonal direction (may also be referred to as a widthwise direction) to the longitudinal direction. The MIM capacitors 20 may be regularly spaced with a predetermined pitch in the orthogonal direction to the longitudinal direction. The MIM capacitors 20 are angled with respect to the upper and lower wirings 30 and 40. The MIM capacitors 20 are arranged diagonally in the wiring mesh. In one instance (see FIG. 3), each of the MIM capacitors 20 may be arranged at about 45 degrees to the upper wiring and lower wiring directions. In other instances (see FIGS. 4 and 5), each MIM capacitor 20 may be arranged at other degrees with respect to the upper wiring and lower wiring directions. Each MIM capacitor 20 includes a top metal 201, a bottom metal 202, and an insulator (not separately depicted in FIGS. 3-6). The top metal 201 and the bottom metal 202 are arranged in parallel with one another in a vertical direction (for example, a Z-axis direction perpendicular to the X-axis and Y-axis directions in the drawing). The insulator is provided between the top metal 201 and the bottom metal 202. The top metal 202, the bottom metal 203, and the insulator are elongated in the same direction on the X-Y axes plane and at the intermediate angle between the upper wiring and lower wiring directions. The bottom metal 202 may have a greater width than the top metal 201 in the widthwise direction. The bottom metal 202 may have a greater length than the top metal 201 in the longitudinal direction.

In the example configurations, the upper wirings 30 include a plurality of sets of upper wirings (may also be referred to as upper wiring sets) 30A-30C. Each set includes a first upper wiring 30a, a second upper wiring 30b, a third upper wiring 30c, and a fourth upper wiring 30d. The upper wiring sets 30A-30C are repeatedly arranged in parallel with one another in the second horizontal (Y-axis) direction. Similarly, the lower wirings 40 include a plurality of sets of lower wirings (may also be referred to as lower wiring sets) 40A-40C. Each set includes a first lower wiring 40a, a second lower wiring 40b, a third lower wiring 40c, and a fourth lower wiring 40d. The lower wiring sets 40A-40C are repeatedly arranged in parallel with one another in the first horizontal (X-axis) direction. The first upper wiring 30a and the first lower wiring 40a may constitute or used as a pair for a first type of power supply. The second upper wiring 30b and the second lower wiring 40b may be a pair for a second type of power supply. The third upper wiring 30c and the third lower wiring 40c may be a pair for a third type of power supply. The fourth upper wiring 30d and the fourth lower wiring 40d may be a pair for a fourth type of power supply. The number of the wiring sets and the number of the wirings in each set are not limited to the illustrated configuration; they may be determined based on designs, specifications, and the like.

In the example configurations, each MIM capacitor 20 is coupled to at least one or more upper wirings 30 by vias 50. In some instances, additionally or alternatively, each MIM capacitor 20 may be coupled to one or more lower wirings 40 by other vias (not separately depicted). Each MIM capacitor 20 may have the top metal 201 coupled to at least one or more upper wirings 30 by one or more vias 51 (50). Each MIM capacitor 20 may have the bottom metal 202 coupled to at least one or more upper wirings 30 by one or more vias 52 (50). The top metal 201 may have one or more protruding parts 210 that receive the vias 51 for coupling to corresponding ones of the upper wirings 30. The bottom metal 202 may have one or more protruding parts 220 that receive the vias 52 for coupling to corresponding ones of the upper wirings 30. For the sake of simplifying the drawings, not all protruding parts are denoted as 210 and 220. The protruding parts 210 each project from at least one of longitudinal sides of the top metal 201 at an oblique angle with respect to the upper and lower wirings 30 and 40. The protruding parts 210 each extend in an orthogonal direction to the longitudinal direction of the top metal 201. Each of the protruding parts 210 reaches a position where the via 51 is provided extending vertically (in the Z-axis direction in the drawing) to couple the protruding part 210 to at least corresponding one of the upper wirings 30. Similarly, the protruding parts 220 each project from at least one of longitudinal sides of the bottom metal 202 at an oblique angle with respect to the upper and lower wirings 30 and 40. The protruding parts 220 each extend in an orthogonal direction to the longitudinal direction of the bottom metal 202. Each of the protruding parts 220 reaches a position where the via 52 is provided extending vertically (in the Z-axis direction in the drawing) to couple the protruding part 220 to at least corresponding one of the upper wirings 30. The protruding parts 210 and 220 are arranged at positions in a horizontal plane to receive the corresponding vias 51 and 52 and to be coupled to the corresponding upper wirings 30 without blocking each other. The protruding parts 210 and 220 may be provided adjacently to each other with a predetermined pitch. The predetermined pitch may correspond to a dimension of the wiring mesh including a distance between the upper wirings 30, a distance between the lower wirings 40, a width of each upper wiring 30, a width of each lower wiring 40, and the like. Furthermore, in areas of the wiring mesh other than the areas where the protruding parts 210 and 220 and the vias 51 and 52 are provided, the upper wirings 30 and the lower wirings 40 may also be coupled to one another by vias 60 at appropriate positions for supply power enhancement. The protruding parts 210 and 220 and the vias 51 and 52 are arranged at positions to avoid the vias 60 so that they do not interfere or block one another. The vias 51 and 52 and the via 60 may be regularly spaced with a predetermined pitch in the diagonal direction in the wiring mesh. The vias 51 and 52 and the via 60 may be arranged at the corresponding intersections of the paired upper and lower wirings 30a and 40a, the paired upper and lower wirings 30b and 40b, the paired upper and lower wirings 30c and 40c, and the paired upper and lower wirings 30d and 40d. The protruding parts 210 and 220 are arranged to receive the corresponding vias 51 and 52 while not overlapping with the via 60.

As one example, in FIG. 3, with respect to one area (see AA) of the wiring mesh where the upper wiring set 30A and the lower wiring set 40A intersect each other in plan view, the top metal 201 of one of the MIM capacitors 20 (see 20i) includes the protruding part 210 where the via 51 is provided to couple the top metal 201 to corresponding one of the upper wirings 30 (see 30c) of the upper wiring set 30A. The protruding part 210 projects from one longitudinal side of the top metal 201 at an oblique angle with respect to the upper and lower wirings 30 and 40. The protruding part 210 extends in an orthogonal direction to the longitudinal direction of the top metal 201. The protruding part 210 reaches a position where the via 51 is provided extending vertically to couple the protruding part 210 to the corresponding upper wiring 30c in the area AA. Similarly, the top metal 201 of another one of the MIM capacitors 20 (see 20ii) adjacent to the MIM capacitor 20i includes the protruding part 210 where the via 51 is provided to couple the top metal 201 to another corresponding one of the upper wirings 30 (see 30b) of the upper wiring set 30A. The protruding part 210 of the MIM capacitor 20ii projects from one longitudinal side of the top metal 201 of the MIM capacitor 20ii facing the top metal 201 of the MIM capacitor 20i and in a direction opposite to the direction of the protruding part 210 of the MIM capacitor 20i. The protruding part 210 of the MIM capacitor 20ii is also shifted in the horizontal plane (for example, in the X-axis direction) from the protruding part 210 of the MIM capacitor 20i so that it reaches the position to receive the via 51 for coupling to the corresponding upper wiring 30b. The protruding parts 210 of the neighboring MIM capacitors 20i and 20ii are coupled to the corresponding upper wirings 30c and 30b by the corresponding vias 51, respectively, without interfering each other. The protruding parts 210 are provided adjacently to each other with a predetermined pitch.

Still looking at the area AA, the bottom metal 202 of the MIM capacitor 20ii includes the protruding part 220 where the via 52 is provided for coupling to another corresponding one of the upper wirings 30 (see 30a) of the upper wiring set 30A. The protruding part 220 projects from one longitudinal side of the bottom metal 202 that is the same longitudinal side of the top metal 201 where the protruding part 210 is provided. The protruding part 220 extends at the same oblique angle and in the same direction as the protruding part 210 of the top metal 201. The protruding part 220 is also shifted in the X-axis direction from the protruding part 210 so that it reaches the position to receive the via 52 for coupling to the corresponding upper wiring 30a. The protruding part 220 of the bottom metal 202 is coupled to the corresponding upper wiring 30a by the via 52 without being blocked by the protruding part 210 of the top metal 201. The protruding part 220 and the protruding part 210 are provided adjacently to each other with a predetermined pitch.

Still furthermore, in the area AA, one of the upper wirings 30 (see 30d) of the upper wiring set 30A and one of the lower wirings 40 (see 40d) of the lower wiring set 40A are coupled to each other by the via 60 arranged at the intersection of the upper wiring 30d and the lower wiring 40d. In the area AA, all the protruding parts 210 and 220 of the MIM capacitors 20i and 20ii and the vias 51 and 52 are arranged at the positions to avoid the via 60. The vias 51 and 52 and the via 60 may be regularly spaced with a predetermined pitch in the diagonal direction in the wiring mesh. The vias 51 and 52 and the via 60 may be aligned between the MIM capacitors 20i and 20ii and along the longitudinal direction of the MIM capacitors 20i and 20ii. The vias 51 and 52 and the via 60 are arranged at the corresponding intersections of the pair of the upper and lower wirings 30a and 40a for the first type of power supply, the pair of the upper and lower wirings 30b and 40b for the second type of power supply, the pair of the upper and lower wirings 30c and 40c for the third type of power supply, and the pair of the upper and lower wirings 30d and 40d for the fourth type of power supply. The protruding parts 210 and 220 of the top metal 201 and the bottom metal 202 of each MIM capacitor 20 are arranged to receive the corresponding vias 51 and 52 while not overlapping with the via 60.

Similarly to the above coupling configuration in the area AA, in another area AB of the wiring mesh where the upper wiring set 30A crosses the lower wiring set 40B in plan view, the MIM capacitor 20ii includes the protruding part 210 on another longitudinal side opposite to the longitudinal side where the protruding parts 210 and 220 in the area AA are provided. The protruding part 210 in the area AB is for coupling to the corresponding upper wiring 30b of the upper wiring set 30A by the via 51. In the area AB, another MIM capacitor 20iii adjacent to the MIM capacitor 20ii includes the protruding parts 210 and 220 on one longitudinal side thereof for coupling to the corresponding upper wirings 30d and 30a by the vias 51 and 52, respectively. The MIM capacitor 20iii further includes the protruding part 220 projecting from the bottom metal 202 for coupling to the upper wiring 30a of the upper wiring set 30A. The protruding part 220 of the MIM capacitor 20iii is adjacent to the protruding part 210 of the MIM capacitor 20ii with a predetermined pitch along the longitudinal direction of the MIM capacitors 20ii and 20iii. Furthermore, the upper wiring 30c of the upper wiring set 30A and the lower wiring 40c of the lower wiring set 40B are coupled by the vias 60 without being interfered by the protruding parts 210 and 220 and the vias 51 and 52. In still another area AC, the upper wiring 30b of the upper wiring set 30A and the lower wiring 40b of the lower wiring set 40C are coupled to each other by the via 60 while the upper wirings 30d and 30c are coupled to the top metals 201 of the MIM capacitors 20iii and 20iv by the corresponding vias 52, respectively, and the upper wiring 30a of the upper wiring set 30A is coupled to the bottom metal 202 of the MIM capacitor 20iv by the via 52. The vias 51 and 52 and the via 60 may be aligned with a predetermined pitch between the neighboring MIM capacitors 20 (20ii and 20iii in AB or 20iii and 20iv in AC) and along the longitudinal direction of the MIM capacitors 20 (20ii and 20iii in AB or 20iii and 20iv in AC).

Although not all via coupling configurations depicted in FIG. 3 are described in detail herein, all areas where the upper wiring sets 30B-30C intersect with the lower wiring sets 40A-40C have similar coupling configurations to those described above. In some areas, however, the MIM capacitors 20 adjacent to each other may share one or more protruding parts 220 coupled to the same upper wirings 30. For example, with respect to the upper wiring 30a of the upper wiring set 30C, the MIM capacitor 20v and the MIM capacitor 20vi have one protruding part 220 connected to their bottom metals 202 at both ends of the protruding part 220, and this protruding part 220 is coupled to the upper wiring 30a of the upper wiring set 30C by one via 51. In a similar manner, the MIM capacitor 20v also shares one protruding part 220 with the MIM capacitor 20iv, and the MIM capacitor 20iv shares one protruding part 220 with the MIM capacitor 20iii. A similar configuration may be provided between the MIM capacitors 20v and 20iv, between the MIM capacitors 20iv and 20iii and between the MIM capacitors 20iii and 20ii with respect to the upper wiring 30a of the upper wiring set 30B. In such configuration, as one example, the bottom metals 202 of the adjacent MIM capacitors 20 may receive, via the shared protruding part 220, the same ground or negative power supply voltage (such as VSS) from the corresponding upper wiring 30 whereas the top metals 201 of the adjacent MIM capacitors 20 may receive, via the individual protruding parts 210, a positive power supply voltage (such as VDD) from the corresponding upper wirings 30 different from the one the bottom metals 202 are coupled to. The top metals 201 and the bottom metals 202 may be coupled to a first voltage (for example, an upper level voltage such as VDD) and a second voltage (for example, a lower level voltage such as VSS), respectively. In another embodiment, the top metals 201 and the bottom metals 202 among the MIM capacitors 20 may be coupled to different voltages. For example, the top metal 201 and the bottom metal 202 of one MIM capacitor (which may be referred to as a first MIM capacitor) 20 may be coupled to a first voltage and a second voltage, respectively, whereas the top metal 201 and the bottom metal 202 of another MIM capacitor (which may be referred to as a second MIM capacitor) 20 may be coupled to a third voltage and a fourth voltage, respectively. The first and second voltages and the third and fourth voltages may be different from each other. The first MIM capacitor and the second MIM capacitor may be adjacent to each other in one instance or may not be adjacent to each other in another instance.

Referring to the example configuration in FIG. 4, each of the upper wirings 30 is formed wider in the Y-axis direction than that in the example configuration in FIG. 3, broadening the area of the upper wirings 30 in the wiring mesh in plan view. In this configuration, the MIM capacitors 20 slant or lean towards the Y-axis more than those in FIG. 3. The MIM capacitors 20 in FIG. 4 each have a smaller acute angle with respect to the Y-axis than those in FIG. 3. Also, while most of the MIM capacitors 20 have the same configurations of the protruding parts 210 and 220 of the top and bottom metals 201 and 202 as those in FIG. 3, some of the MIM capacitors 20 have different coupling configurations. For example, the upper wiring 30d of the upper wiring set 30C and the lower wiring 40d of the lower wiring set 40C are coupled to each other by the via 60 in FIG. 4 whereas the top metal 201 of the MIM capacitor 20vi in FIG. 3 has the protruding part 210 coupled to the upper wiring 30d of the upper wiring set 30C by the via 51. The top metal 201 of the MIM capacitor 20vi in FIG. 4 has the protruding part 210 coupled to the upper wiring 30c of the upper wiring set 30C by the via 51 whereas at the corresponding position in FIG. 3, the upper wiring 30c of the upper wiring set 30C and the lower wiring 40c of the lower wiring set 40C are coupled to each other by the via 60. In FIG. 4, the upper wiring 30d of the upper wiring set 30C and the lower wiring 40d of the lower wiring set 40A are coupled to each other by the via 60 whereas at the corresponding position in FIG. 3, the top metal 201 of the MIM capacitor 20iii has the protruding part 210 coupled to the upper wiring 30d of the upper wiring set 30C by the via 51.

Referring to the example configuration in FIG. 5, each of the lower wirings 40 is formed wider in the X-axis direction than that in the example configuration in FIG. 3, broadening the area of the lower wirings 40 in the wiring mesh in plan view. In this configuration, the MIM capacitors 20 slant or lean towards the X-axis more than those in FIG. 3. The MIM capacitors 20 in FIG. 5 each have a smaller acute angle with respect to the X-axis than those in FIG. 3. Also, while most of the MIM capacitors 20 have the same configurations of the protruding parts 210 and 220 of the top and bottom metals 201 and 202 as those in FIG. 3, some of the MIM capacitors 20 have different coupling configurations. For example, the upper wiring 30d of the upper wiring set 30C and the lower wiring 40d of the lower wiring set 40C are coupled to each other by the via 60 in FIG. 5 whereas the top metal 201 of the MIM capacitor 20vi in FIG. 3 has the protruding part 210 coupled to the upper wiring 30d of the upper wiring set 30C by the via 51. The upper wiring 30c of the upper wiring set 30C and the lower wiring 40c of the lower wiring set 40A are coupled to each other by the via 60 in FIG. 5 whereas the top metal 201 of the MIM capacitor 20iv has the protruding part 210 coupled to the upper wiring 30d of the upper wiring set 30C by the via 51.

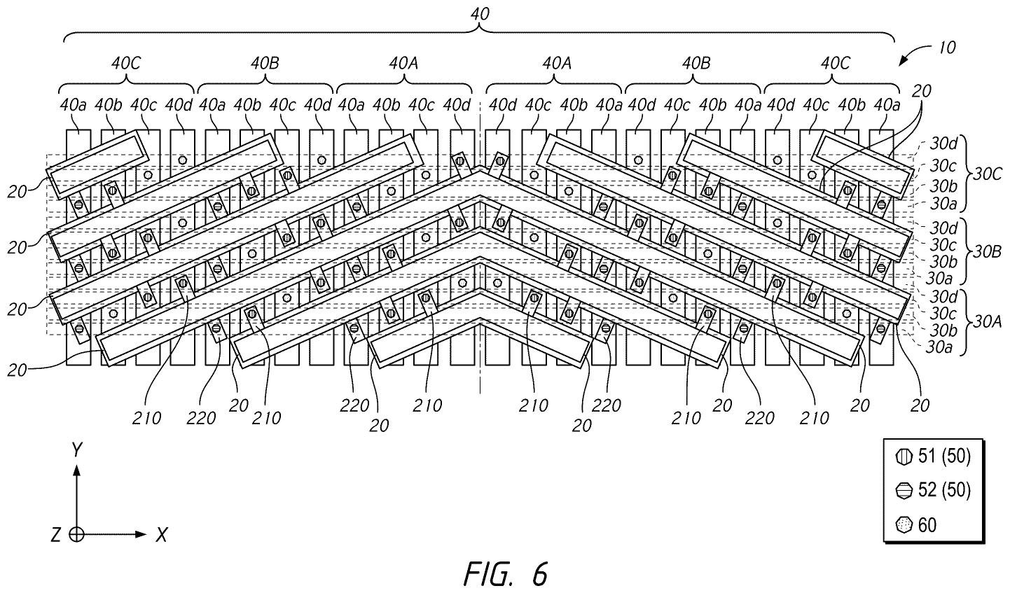

Referring to the example configuration in FIG. 6, the example configuration in FIG. 5 is mirror inverted at a vertical dotted line. The configuration on the right side of the vertical dotted line is a mirror image of the configuration (which is substantially the same as that in FIG. 5) on the left side of the vertical dotted line. The two configurations may form one extended configuration in the X-axis direction with the upper wirings 30 extending therethrough. The lower wiring sets 40A-40C are mirror inverted. The MIM capacitors 20 and their coupling configurations to the upper and lower wirings 30 and 40 by the protruding parts 210 and 220 and the vias 51 and 52 are also mirror inverted.

As described using the various example configurations, the arrangement of the MIM capacitors 20 and the protruding parts 210 and 220 according to the present embodiment makes the coupling configurations to the upper and lower wirings 30 and 40 by the corresponding vias 50 (51 and 52) further flexible and can realize an improved balance between capacitance arrangement and power enhancement. Efficiency in reducing the resistance can also be increased. Furthermore, even with a complex power supply network, such as the wiring mesh described above, the top metal 201 and/or the bottom metal 202 of each MIM capacitor 20 can be made larger, and hence the MIM capacitor 20 can further efficiently perform as a capacitive element. In the case of a multi-power mesh, such as the wiring mesh as described above, the MIM capacitors 20 can be efficiently arranged without interfering with the coupling of other power sources by the vias 60. There is further flexibility in arrangement of the unit cell including the MIM capacitor 20, improving design efficiency. The power source combination can be further easily changed by simply changing the arrangement of the protruding parts 210 and 220 that receive the vias 50, still further improving design efficiency. The number of the upper and lower wirings 30 and 40 and hence the number of power lines as well as the number of the vias 50 can be significantly increased. The area used for the MIM capacitors 20 can be increased because the MIM capacitors 20 is formed in an elongated shape rather than being separated at multiple positions.

In the present embodiments described above, one example of the semiconductor device may be a DRAM. However, a DRAM is merely one example, and the embodiments and the descriptions herein are not intended to be limited to a DRAM. Memory devices other than a DRAM, such as a static random-access memory (SRAM), a flash memory, an erasable programmable read-only memory (EPROM), a magnetoresistive random-access memory (MRAM), and a phase-change memory, can also be applied as the semiconductor device. Furthermore, devices other than memory devices, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a plurality of upper wirings each extending in a first horizontal direction;
a plurality of lower wirings each extending in a second horizontal direction perpendicular to the first horizontal direction; and
a plurality of metal-insulator-metal (MIM) capacitors each extending at an intermediate angle between the first horizontal direction and the second horizontal direction.

2. The apparatus according to claim 1, wherein the MIM capacitors are arranged between the upper wirings and the lower wirings and are coupled to at least one of the upper wirings or the lower wirings.

3. The apparatus according to claim 1, wherein the upper wirings and the lower wirings are orthogonal to each other in a mesh configuration, and the MIM capacitors are angled with respect to the upper wirings and the lower wirings.

4. The apparatus according to claim 3, wherein the upper wirings are arranged in parallel with one another in the second horizontal direction, and the lower wirings are arranged in parallel with one another in the first horizontal direction.

5. The apparatus according to claim 1, wherein at least one of the upper wirings or the lower wirings include power supply wirings, and the MIM capacitors include compensation capacitors.

6. The apparatus according to claim 1, wherein
each of the MIM capacitors includes a top metal, a bottom metal, and an insulator between the top metal and the bottom metal, and
the top metal, the bottom metal, and the insulator extend at the intermediate angle between the first horizontal direction and the second horizontal direction.

7. The apparatus according to claim 6, wherein the top metal is coupled to a corresponding upper wiring of the plurality of upper wirings by a via.

8. The apparatus according to claim 7, wherein the top metal includes a protruding part coupled to the corresponding upper wiring by the via.

9. The apparatus according to claim 6, wherein the bottom metal is coupled to a corresponding upper wiring of the plurality of upper wirings by a via.

10. The apparatus according to claim 9, wherein the bottom metal includes a protruding part coupled to the corresponding upper wiring by the via.

11. The apparatus according to claim 6, wherein the top metal is coupled to a first voltage, and the bottom metal is coupled to a second voltage.

12. An apparatus, comprising:
a plurality of upper wirings each extending in a first horizontal direction;
a plurality of lower wirings each extending in a second horizontal direction perpendicular to the first horizontal direction; and
a plurality of metal-insulator-metal (MIM) capacitors between the upper wirings and the lower wirings and each extending at an intermediate angle between the first horizontal direction and the second horizontal direction, wherein
each of the MIM capacitors includes a top metal, a bottom metal, and an insulator between the top metal and the bottom metal, the top metal, the bottom metal, and the insulator extending at the intermediate angle between the first horizontal direction and the second horizontal direction,
the top metal is coupled to a first corresponding upper wiring of the plurality of upper wirings by a first via, and
the bottom metal is coupled to a second corresponding upper wiring of the plurality of upper wirings by a second via.

13. The apparatus according to claim 12, wherein
the upper wirings are arranged in parallel with one another in the second horizontal direction,
the lower wirings are arranged in parallel with one another in the first horizontal direction,
the upper wirings and the lower wirings are orthogonal to each other in a mesh configuration, and
the top metal, the bottom metal and the insulator of each of the MIM capacitors are angled with respect to the upper wirings and the lower wirings.

14. The apparatus according to claim 12, wherein
the top metal includes a first protruding part coupled to the first corresponding upper wiring by the first via, and,
the bottom metal includes a second protruding part coupled to the second corresponding upper wiring by the second via.

15. The apparatus according to claim 14, wherein
the first protruding part of the top metal projects from at least one of longitudinal sides of the top metal, and
the second protruding part of the bottom metal projects from at least one of longitudinal sides of the bottom metal.

16. The apparatus according to claim 12, wherein at least one of the upper wirings or the lower wirings include power supply wirings, and the MIM capacitors include compensation capacitors.

17. The apparatus according to claim 12, wherein the top metal is coupled to a first voltage, and the bottom metal is coupled to a second voltage.

18. An apparatus, comprising:
a plurality of upper wirings in an upper metal layer and a plurality of lower wirings in a lower metal layer, the upper wirings and the lower wirings arranged in a mesh configuration; and
a plurality of metal-insulator-metal (MIM) capacitors between the upper wirings and the lower wirings, each of the MIM capacitors arranged diagonally in the mesh configuration and coupled to at least one of the upper wirings or the lower wirings by one or more vias.

19. The apparatus according to claim 18, wherein
each of the MIM capacitors includes a top metal, a bottom metal, and an insulator between the top metal and the bottom metal, the top metal, the bottom metal, and the insulator elongated diagonally in the mesh configuration, and
at least one of the top metal or the bottom metal is coupled to a corresponding upper wiring of the upper wirings by a corresponding via of the one or more vias.

20. The apparatus according to claim 19, wherein the top metal includes a protruding part configured to receive the corresponding via to be coupled to the corresponding upper wiring.

21. The apparatus according to claim 19, wherein the bottom metal includes a protruding part configured to receive the corresponding via to be coupled to the corresponding upper wiring.

22. The apparatus according to claim 18, wherein at least one of the upper wirings or the lower wirings include power supply wirings, and the MIM capacitors include compensation capacitors.

23. The apparatus according to claim 18, wherein the top metal is coupled to a first voltage, and the bottom metal is coupled to a second voltage.
